(19) United States
(12) Patent Application Publication
(10) Pub. No.: US 2026/0107664 A1
(43) Pub. Date: Apr. 16, 2026

(54) DISPLAY PANEL, FORMING METHOD THEREFOR AND DISPLAY DEVICE

(71) Applicant: WUHAN TIANMA MICROELECTRONICS CO., LTD., Wuhan (CN)

(72) Inventors: Zhaodi YIN, Wuhan (CN); Yangzhao MA, Wuhan (CN)

(21) Appl. No.: 19/421,425

(22) Filed: Dec. 16, 2025

Related U.S. Application Data
(63) Continuation of application No. PCT/CN2025/071163, filed on Jan. 8, 2025.

(30) Foreign Application Priority Data
Nov. 27, 2024 (CN) 202411722707.3

(51) Int. Cl. H10K 59/80; H10K 59/12; H10K 59/122

(52) U.S. Cl. CPC H10K 59/8723; H10K 59/1201; H10K 59/122; H10K 59/8792

(57) ABSTRACT

Provided are a display panel, a forming method therefor and a display device. The display panel includes a substrate, light-emitting devices and spacers located on a same side of the substrate. An orthographic projection of one of the spacers onto the substrate is located between orthographic projections of adjacent ones of the light-emitting devices onto the substrate. The display panel has a first cross-section perpendicular to a plane of the substrate. In the first cross-section, one of the spacers includes a bottom edge, a bevel edge and an arc edge. The bottom edge is an edge of the spacer close to the substrate. The arc edge connects the bottom edge and the bevel edge, an angle formed between the bevel edge and the plane of the substrate and facing outside of the spacer is an acute angle. The arc edge is recessed towards inside of the spacer.

This application is a continuation of International Application No. PCT/CN2025/071163, filed on Jan. 8, 2025, which claims priority to Chinese Patent Application No. 202411722707.3, filed on Nov. 27, 2024. All of the aforementioned applications are hereby incorporated by reference in their entireties.

### TECHNICAL FIELD

The present disclosure relates to the field of display technologies, and in particular, to a display panel, a forming method for a display panel and a display device.

### BACKGROUND

An organic self-light-emitting display panel has the characteristics of self-light-emission. The organic self-light-emitting display panel does not need to be provided with a backlight source and is lighter and thinner than a liquid crystal display panel. The organic self-light-emitting display panel also has advantages such as high brightness, low power consumption, fast response, high definition, good flexibility, and high light-emission efficiency, which can meet new demands of consumers on display technologies. An organic functional layer of each light-emitting device in the organic light-emitting display panel is formed to be an entire surface by an evaporation process. Additionally, spacers are usually provided to partially insulate part of the organic functional layer, in order to reduce a leakage current between the light-emitting devices. When further forming the inorganic encapsulation layer on the spacer, there is a problem of encapsulation failure caused by local cracking of the inorganic encapsulation layer.

### SUMMARY

Embodiments of the present disclosure provide a display panel, a forming method for a display panel and a display device, aiming to solve the technical problem in terms of improving the encapsulation reliability of the display panel.

In a first aspect, an embodiment of the present disclosure provides a display panel. The display panel includes a substrate, light-emitting devices and spacers that are located on a same side of the substrate. An orthographic projection of one of the spacers onto the substrate is located between orthographic projections of adjacent ones of the light-emitting devices onto the substrate. The display panel has a first cross-section perpendicular to a plane of the substrate. In the first cross-section, one of the spacers includes a bottom edge, a bevel edge and an arc edge; the bottom edge is an edge of the spacer close to the substrate, the arc edge connects the bottom edge and the bevel edge, an angle formed between the bevel edge and the plane of the substrate and facing outside of the spacer is an acute angle, and the arc edge is recessed towards inside of the spacer.

In a second aspect, based on a same inventive concept, an embodiment of the present disclosure provides a display device, including a display panel. The display panel includes a substrate, light-emitting devices and spacers that are located on a same side of the substrate. An orthographic projection of one of the spacers onto the substrate is located between orthographic projections of adjacent ones of the light-emitting devices onto the substrate. The display panel has a first cross-section perpendicular to a plane of the substrate. In the first cross-section, one of the spacers includes a bottom edge, a bevel edge and an arc edge; the bottom edge is an edge of the spacer close to the substrate, the arc edge connects the bottom edge and the bevel edge, an angle formed between the bevel edge and the plane of the substrate and facing outside of the spacer is an acute angle, and the arc edge is recessed towards inside of the spacer.

In a third aspect, based on a same inventive concept, an embodiment of the present disclosure provides a forming method for a display panel, including: forming light-emitting devices and spacers on a side of a substrate, an orthographic projection of one of the spacers onto the substrate being located between orthographic projections of adjacent ones of the light-emitting devices onto the substrate; and a forming method for one of the spacers includes: coating a photoresist material, and forming an embryonic form of the spacer by an exposure-development step; performing IUV irradiation treatment on the embryonic form of the spacer to obtain an initial form of the spacer; and obtaining the spacer by curing the initial form of the spacer, wherein the spacer includes an arc edge; the display panel has a first cross-section perpendicular to a plane of the substrate; and in the first cross-section, the spacer includes a bottom edge, a bevel edge and the arc edge; the bottom edge is an edge of the spacer close to the substrate, the arc edge connects the bottom edge and the bevel edge, an angle formed between the bevel edge and the plane of the substrate and facing outside of the spacer is an acute angle, and the arc edge is recessed towards inside of the spacer.

The embodiments of the present disclosure provide a display panel, a forming method for a display panel and a display device, having following beneficial effects. According to the display panel provided by the embodiments of the present disclosure, the spacer in the inverted trapezoidal shape is provided between adjacent light-emitting devices. The organic functional layer in the light-emitting device may be disconnected by the spacer, thereby reducing the leakage current between adjacent light-emitting devices. The spacer includes an arc edge, which connects the bottom edge and the bevel edge, enabling a bottom angle of the spacer close to the substrate is an arc bottom angle. When forming the inorganic encapsulation layer, the inorganic material may be well deposited and smoothly transited at the arc bottom angle of the spacer, avoiding the problem of forming encapsulation cavities and cracks at the bottom angle of the spacer, and thus improving the encapsulation reliability of the display panel.

### BRIEF DESCRIPTION OF DRAWINGS

In order to better illustrate the technical solutions in the embodiments of the present disclosure or the related art, the drawings used in the description of the embodiments will be briefly illustrated as follows. It should be noted that, the drawings described below are merely some of, rather than all of the embodiments of the present disclosure. Based on these drawings, those skilled in the art can obtain other drawings without any creative efforts.

FIG. 1 is a schematic cross-sectional diagram of a display panel in the related art;

FIG. 2 is a schematic diagram of a display panel according to an embodiment of the present disclosure;

FIG. 3 is a schematic cross-sectional diagram of FIG. 2 along line A-A′;

FIG. 4 is a schematic diagram of stacking of a light-emitting device according to an embodiment of the present disclosure;

FIG. 5 is a schematic cross-sectional diagram of another display panel according to an embodiment of the present disclosure;

FIG. 6 is a schematic cross-sectional diagram of another display panel according to an embodiment of the present disclosure;

FIG. 7 is a schematic cross-sectional diagram of another display panel according to an embodiment of the present disclosure;

FIG. 8 is a schematic cross-sectional diagram of another display panel according to an embodiment of the present disclosure;

FIG. 9 is a partial schematic diagram of another display panel according to an embodiment of the present disclosure;

FIG. 10 is a simplified schematic cross-sectional diagram of FIG. 9 along line B-B′;

FIG. 11 is a schematic cross-sectional diagram of another display panel according to an embodiment of the present disclosure;

FIG. 12 is a schematic cross-sectional diagram of another display panel according to an embodiment of the present disclosure;

FIG. 13 is a partial schematic diagram of another display panel according to an embodiment of the present disclosure;

FIG. 14 is a partial schematic diagram of another display panel according to an embodiment of the present disclosure;

FIG. 15 is a partial schematic diagram of another display panel according to an embodiment of the present disclosure;

FIG. 16 is a partial schematic diagram of another display panel according to an embodiment of the present disclosure;

FIG. 17 is a flowchart of a forming method for a display panel according to an embodiment of the present disclosure; and

FIG. 18 is a schematic diagram of a display device according to an embodiment of the present disclosure.

### DESCRIPTION OF EMBODIMENTS

In order to better illustrate objectives, technical solutions, and advantages of embodiments of the present disclosure, the technical solutions in embodiments of the present disclosure are described in details with reference to the drawings. It should be noted that, the embodiments described are only some rather than all of the embodiments of the present disclosure. Based on the embodiments of the present disclosure, all other embodiments obtained by those ordinary skilled in the art without creative efforts shall fall within the protection scope of the present disclosure.

Various modifications and changes may be made to the present disclosure without departing from the spirt or scope of the present disclosure, which are obvious to those skilled in the art. Accordingly, the present disclosure is intended to cover the modifications and variations of the present disclosure that fall within the scope of corresponding claims (claimed technical solutions) and their equivalents. It should be noted that the embodiments in the present disclosure can be combined mutually in the case of no conflict.

Terms used in the embodiments of the present disclosure are only for the purpose of describing specific embodiments but not intended to limit the present disclosure. The terms “a/an”, and “the/said” in a singular form in the embodiments of the present disclosure and the attached claims are also intended to include plural forms thereof, unless explicitly noted otherwise in the context.

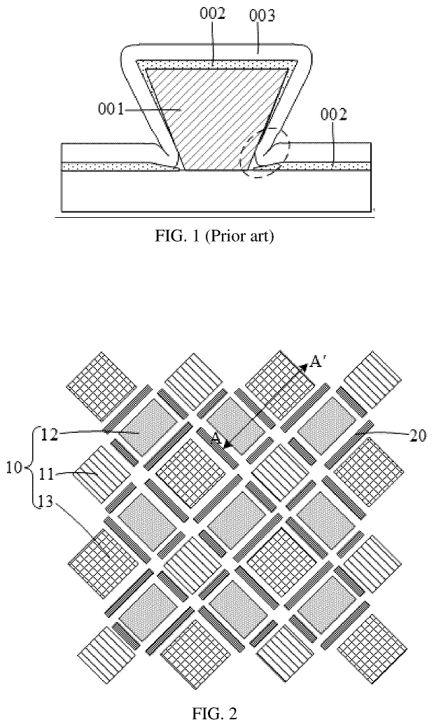

FIG. 1 is a schematic cross-sectional diagram of a display panel in the related art. As shown in FIG. 1, the display panel includes a spacer 001, an organic functional layer 002 disconnected by the spacer 001, and an inorganic encapsulation layer 003 covering the organic functional layer 002. The spacer 001 has an inverted trapezoidal shape. Due to the relatively sharp bottom angle of the inverted trapezoid, the inorganic encapsulation layer 003 cannot be deposited well at the bottom angle, making it prone to forming cavities and gaps, as shown in the position circled by the dashed line in FIG. 1. The inorganic encapsulation layer 003 at a gap position is prone to fracture along a gap direction and extends to the cavity position, resulting in poor encapsulation of the inorganic encapsulation layer 003 and thereby affecting the encapsulation reliability of the display panel.

In order to solve the problems existing in the related art, embodiments of the present disclosure provide a display panel, which improves the morphology of the bottom angle of the spacer to improve the morphology of the inorganic encapsulation layer deposited at the bottom angle and to reduce the risk of cracks generated at the inorganic encapsulation layer. Further, in some embodiments, the morphology at the top angle of the spacer is improved, so that a relatively thick inorganic encapsulation layer can be deposited on a sidewall of the spacer, thereby further improving the encapsulation reliability of the inorganic encapsulation layer.

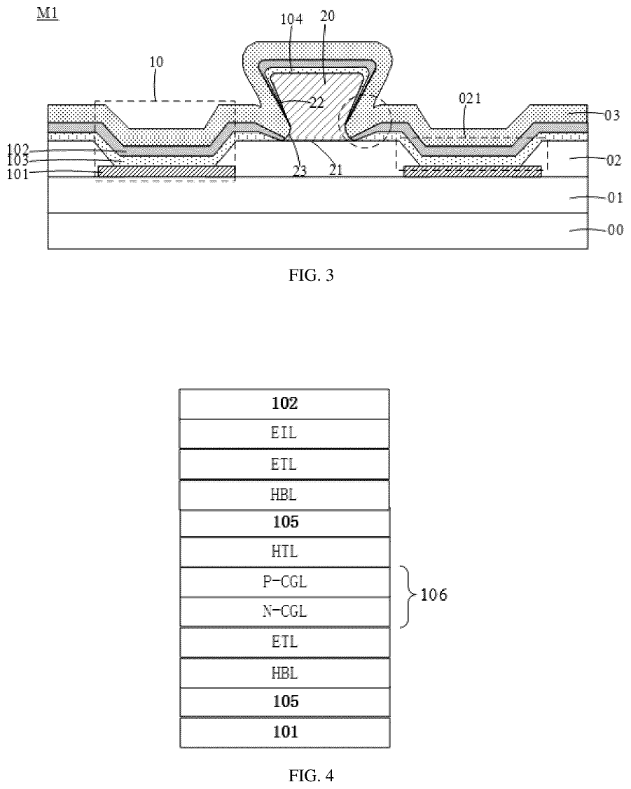

FIG. 2 is a schematic diagram of a display panel according to an embodiment of the present disclosure, and FIG. 3 is a schematic cross-sectional diagram of FIG. 2 along line A-A′. FIG. 2 illustrates the arrangement of the light-emitting devices at a local position of the display panel. As shown in FIG. 2, the light-emitting devices 10 include a first light-emitting device 11, a second light-emitting device 12, and a third light-emitting device 13 with different colors. The arrangement of the light-emitting devices 10 in FIG. 2 is merely illustrative and is not intended to limit the present disclosure. It can be seen from FIG. 2 that a spacer 20 is provided between adjacent light-emitting devices 10, that is, an orthographic projection of the spacer 20 onto the substrate 00 is located between orthographic projections of adjacent light-emitting devices 10 onto the substrate 00.

FIG. 3 illustrates a first cross-section M1 of the display panel perpendicular to the plane of the substrate 00. Referring to FIG. 3, the light-emitting device 10 and the spacer 20 are located on a same side of the substrate 00. In the first cross-section M1, the spacer 20 includes a bottom edge 21, a bevel edge 22 and an arc edge 23. The bottom edge 21 is an edge of the spacer 20 close to the substrate 00. The arc edge 23 connects the bottom edge 21 and the bevel edge 22. It can be seen that the angle formed between the bevel edge 22 and the plane of the substrate 00 towards the outside of the spacer 20 is an acute angle. The arc edge 23 is recessed towards the inside of the spacer 20. The spacer 20 is formed as an approximately inverted trapezoidal shape in the first cross-section M1. The arcuate edge 23 may be a partial arc in an approximate circle or an approximate ellipse.

FIG. 3 shows a driving layer 01 provided with a pixel circuit. The pixel circuit is configured to drive the light-emitting device 10 to emit light. A pixel definition layer 02 is provided on the driving layer 01 and includes a plurality of openings 021. The light-emitting device 10 is located in the opening 021. The light-emitting device 10 includes a first electrode 101, a second electrode 102, and an organic functional layer 103. The organic functional layer 103 is deposited within the opening 021 and extends outside the opening 021. The display panel further includes an organic functional portion 104 covering the spacer 20 on a side of the spacer 20 away from the substrate 00. The organic functional portion 104 is made of a same material as the organic functional layer 103. The organic functional portion 104 is disconnected from the organic functional layer 103 at a position of the spacer 20. When forming the display panel, an organic material layer is formed by an evaporation process. The organic material layer is disconnected by the spacer 20. The organic material deposited in the opening 021 forms the organic functional layer 103, and the organic material which covers the spacer 20 forms the organic functional portion 104. The spacer 20 is configured to disconnect the organic material layer, thereby reducing the leakage current between adjacent light-emitting devices 10. An inorganic encapsulation layer 03 is provided on a side of the light-emitting device 10 and the spacer 20 away from the substrate 00, and covers the light-emitting device 10 and the spacer 20 to form an entire layer.

According to the display panel provided by the embodiments of the present disclosure, the spacer 20 in the inverted trapezoidal shape are provided between adjacent light-emitting devices 10, and the organic functional layers 103 in the light-emitting devices 10 may be disconnected by the spacers 20, thereby reducing the leakage current between the adjacent light-emitting devices 10. The spacer 20 includes an arc edge 23, which connects the bottom edge 21 and the bevel edge 22, enabling a bottom angle of the spacer 20 close to the substrate 00 is an arc bottom angle. When forming the inorganic encapsulation layer 03, the inorganic material may be well deposited and smoothly transited at the arc bottom angle of the spacer 20, avoiding the problem of forming encapsulation cavities and cracks at the bottom angle of the spacer 20, and thus improving the encapsulation reliability of the display panel.

FIG. 3 only illustrates a simplified schematic of the light-emitting device 10. In some embodiments, the light-emitting device 10 includes a light-emitting layer located between the first electrode 101 and the second electrode 102. The organic functional layer 103 includes at least one of a hole injection layer, a hole transport layer, an electron blocking layer, a hole blocking layer, an electron transport layer, and an electron injection layer. In an embodiment, the first electrode 101 is an anode, and the second electrode 102 is a cathode.

In some embodiments, the light-emitting device 10 is a stacked device. FIG. 4 is a schematic diagram of stacking of a light-emitting device according to an embodiment of the present disclosure. As shown in FIG. 4, the light-emitting device 10 includes a first electrode 101 and a second electrode 102, and at least two light-emitting layers 105 located between the first electrode 101 and the second electrode 102. A charge generation layer 106 is provided between adjacent light-emitting layers 105. The charge generation layer 106 includes an n-type charge generation layer N-CGL and a p-type charge generation layer P-CGL. The light-emitting device 10 further includes film layers such as a hole blocking layer HBL, an electron transport layer ETL, a hole transport layer HTL, and an electron injection layer EIL. FIG. 4 illustrates that the light-emitting device 10 includes two light-emitting layers 105. Embodiments of the present disclosure may be applied to a display panel with the stacked device, thereby improving the efficiency of the light-emitting device 10, reducing the power consumption, and prolonging the service life. By adopting the structure of the spacer 20 provided by the embodiments of the present disclosure, the encapsulation reliability may be improved, thereby further prolonging the service life.

As shown in FIG. 3, the display panel includes a pixel definition layer 02 located on a side of the substrate 00. The spacer 20 is located on a side of the pixel definition layer 02 away from the substrate 00. The arc edge 23 is in contact with a surface of the pixel defining layer 02 away from the substrate 00. In this embodiment, a surface of the pixel defining layer 02 is a substrate surface of the spacer 20, and the bottom edge 21 of the spacer 20 is in contact with a surface of the pixel defining layer 02. In the embodiments of the present disclosure, the morphology of the spacer 20 is configured to form an arc bottom angle at the bottom angle position of the spacer 20, thereby improving the deposition morphology of the inorganic encapsulation layer at the position of the bottom angle of the spacer 20, and thus improving the encapsulation reliability of the display panel.

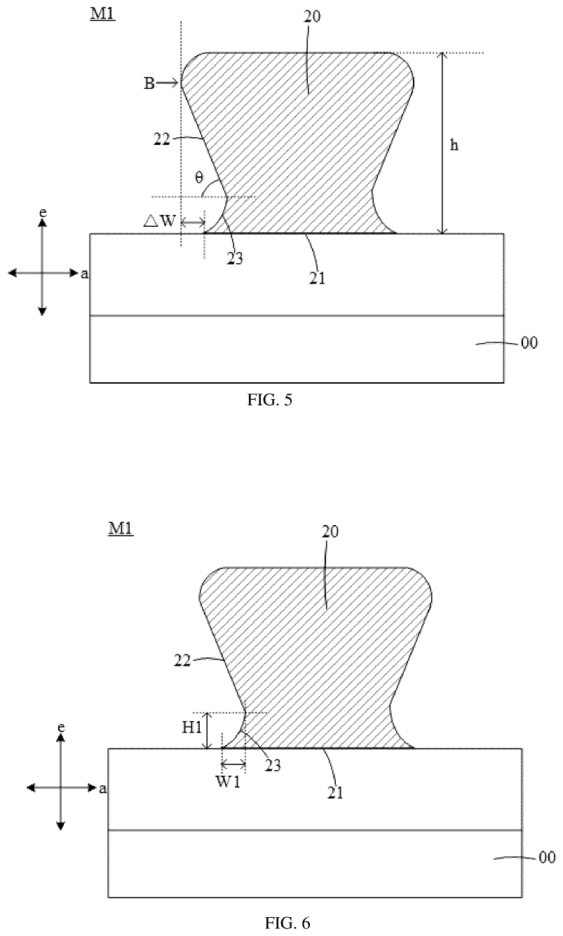

In some embodiments, FIG. 5 is a schematic cross-sectional diagram of another display panel according to an embodiment of the present disclosure, and FIG. 5 only illustrates a position of the spacer 20 in the first cross-section M1. As shown in FIG. 5, in the first cross-section M1, along the first direction a, the arc edge 23 does not exceed an end edge B of the spacer 20 on a side away from the substrate 00. The first direction a is parallel to the plane of the substrate 00. According to this embodiment, the length of the arc edge 23 along the first direction a is not excessively large. On the one hand, the width occupied by the entire spacer 20 along the first direction a is not excessively large, thereby providing a complete spacer 20 between adjacent light-emitting devices 10. On the other hand, the partition effect of the spacer 20 may be ensured, and the inorganic encapsulation layer may be well deposited at the position of the arc edge 23.

As shown in FIG. 5, along the first direction a, a distance between the arc edge 23 and an end edge B of the spacer 20 on a side away from the substrate 00 is ΔW, where ΔW≥h/(3* tan θ). A height of the spacer 20 in a direction e perpendicular to a plane of the substrate 00 is h, and 0 is a first included angle formed between the bevel edge 22 and the plane of the substrate 00 towards the outside of the spacer 20. It can be understood that the height h of the spacer 20 is its own height, that is, a distance between an upper end and a lower end of the spacer 20 along the direction e. According to this embodiment of the present disclosure, ΔW is configured to be related to h and θ, so that a length of ΔW is not excessively small, and the arc edge 23 also has a proper length along the first direction a. Therefore, the partition effect of the spacer 20 can be ensured, and the inorganic encapsulation layer can be well deposited at the arc edge 23, thereby improving the encapsulation reliability.

In some embodiments, as shown in FIG. 5, an angle formed between the bevel edge 22 and the plane of the substrate 00 and facing the outside of the spacer 20 is a first included angle θ, where 45°≤θ≤75°. Such a configuration can ensure the inclination degree of the bevel edge 22 relative to the plane of the substrate 00, thereby ensuring that a good partition effect of the spacer 20 on the evaporation material, and thus alleviating the lateral leakage current between the light-emitting devices 10.

In some embodiments, FIG. 6 is a schematic cross-sectional diagram of another display panel according to an embodiment of the present disclosure, and FIG. 6 only illustrates a position of the spacer 20 in the first cross-section M1. As shown in FIG. 6, along a direction e perpendicular to the plane of the substrate 00, a height of the arc edge 23 is H1. The height H1 of the arc edge 23 may be understood as its own height, that is, the length of the arc edge 23 along the direction e. Along the first direction a, a width of the arc side 23 is W1, and the first direction a is parallel to the plane of the substrate 00, where 0.4≤H1/W1≤2.5. According to this embodiment of the present disclosure, the height H1 and the width W1 of the arc edge 23 meet a certain proportional relationship. In some embodiments, H1 may also be equal to W1. When H1 is greater than W1 or H1 is smaller than W1, values between H1 and W1 do not differ much, thereby achieving smooth transition between the arc edge 23 and the bevel edge 22, and between the arc edge 23 and the substrate surface of the arc edge 23, well depositing the inorganic encapsulation layer at the position of the arc edge 23, avoiding the problem of forming encapsulation cavities and cracks at the position of the bottom angle of the spacer 20, and thus improving the encapsulation reliability of the display panel.

In some embodiments, 0.2 μm≤H1≤0.5 μm, and 0.2 μm≤W1≤0.5 μm. In the display panel, due to the limitation of the process capability and the thickness requirement of the display panel, the height of the spacer 20 is subject to a certain influence. According to this embodiment of the present disclosure, both H1 and W1 meet a certain range, thereby ensuring smooth transition between the arc edge 23 and the bevel edge 22, and between the arc edge 23 and the substrate surface thereof, and thus well depositing the inorganic encapsulation layer at the position of the arc edge 23. Additionally, the ratio of the height of the arc edge 23 to the overall height of the spacer 20 is not excessively large, thereby ensuring the partition effect of the spacer 20 on the evaporation material.

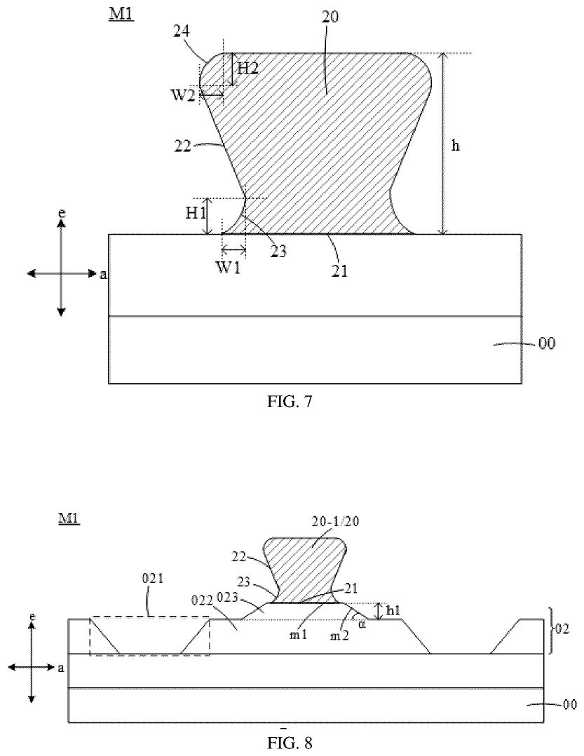

In some embodiments, FIG. 7 is a schematic cross-sectional diagram of another display panel according to an embodiment of the present disclosure, and FIG. 7 only illustrates a position of the spacer 20 in the first cross-section M1. As shown in FIG. 7, a corner of an end of the spacer 20 away from the substrate 00 in the first cross-section M1 is an arc corner 24, which may be a partial arc in an approximate circle or an ellipse. According to this embodiment of the present disclosure, the bottom angle of the spacer 20 close to the substrate 00 is configured as the arc bottom angle, and the corner of the spacer 20 away from the substrate 00 is configured as the arc corner 24. By using the arc bottom angle, the inorganic encapsulation layer can be well deposited at the bottom of the spacer 20, thereby avoiding the problem of forming encapsulation cavities and cracks at the bottom angle of the spacer 20. Using the arc corner 24 may facilitate film formation and extension of the inorganic encapsulation layer on the bevel edge 22, and the cooperation between the arc bottom angle and the arc corner 24 on the spacer 20 may enable the inorganic encapsulation layer to form an entire layer, thereby improving the encapsulation reliability.

As shown in FIG. 7, in the first cross-section M1, along the direction e perpendicular to the plane of the substrate 00, the height H2 of the arc corner 24 is H2. The height H2 of the arc corner 24 may be understood as its own height, that is, the length of the arc corner 24 along the direction e. Along the first direction a, the width of the arc corner 24 is W2, and the first direction a is parallel to the plane of the substrate 00, where 0.5≤H2/W2≤2. According to this embodiment of the present disclosure, the height H2 and the width W2 of the arc corner 24 meet a certain proportional relationship. In some embodiments, H2 may also be equal to W2. When H2 is greater than W2 or H2 is smaller than W2, values between H2 and W2 do not differ much, thereby achieving smooth transition between the arc corner 24 and the bevel edge 22, and between the arc corner 24 and the upper surface of the spacer 20, facilitating the film formation and extension of the inorganic encapsulation layer on the bevel edge 22, and thus improving the encapsulation reliability of the display panel.

In some embodiments, 0.5 μm≤H2≤0.9 μm, and 0.5 μm≤W2≤0.9 μm. Both H2 and W2 are configured to meet a certain range, thereby ensuring smooth transition between the arc corner 24 and the bevel edge 22, and between the arc corner 24 and the upper surface of the spacer 20, and thus ensuring the film formation and extension of the inorganic encapsulation layer on the bevel edge 22. Additionally, the ratio of the height of the arc corner 24 to the overall height of the spacer 20 is not excessively large, thereby ensuring the partition effect of the spacer 20 on the evaporation material.

In some embodiments, as shown in FIG. 7, in the first cross-section M1, along the direction e perpendicular to the plane of the substrate 00, the height of the arc edge 23 is H1, and the height of the arc corner 24 is H2, where H2≥H1. According to this embodiment of the present disclosure, the height of the arc corner 24 is greater than the height of the arc edge 23, thereby reducing the process difficulty and enabling the process simpler and easier to implement.

In some embodiments, as shown in FIG. 7, in the first cross-section M1, along the first direction a, the width of the arc edge 23 is W1, the width of the arc corner 24 is W2, where W2>W1, and the first direction a is parallel to the plane of the substrate 00. In this embodiment of the present disclosure, the width of the arc corner 24 along the first direction a is greater than the width of the arc edge 23, thereby reducing the process difficulty and enabling the process simpler and easier to implement.

In some embodiments, along the direction e perpendicular to the plane of the substrate 00, the height of the arc edge 23 is H1, the height of the arc corner 24 is H2, and the height of the spacer 20 is h, where h−H1−H2≥h/3. That is, the sum of the height H1 of the arc edge 23 and the height H2 of the arc corner 24 does not exceed two-thirds of the height of the spacer 20. Such a configuration may ensure that the bevel edge 22 has a certain length, and in cooperation with the design of the first included angle θ, it can ensure that the spacer 20 has a good partition effect on the evaporation material, thereby effectively alleviating the lateral leakage current between the light-emitting devices 10.

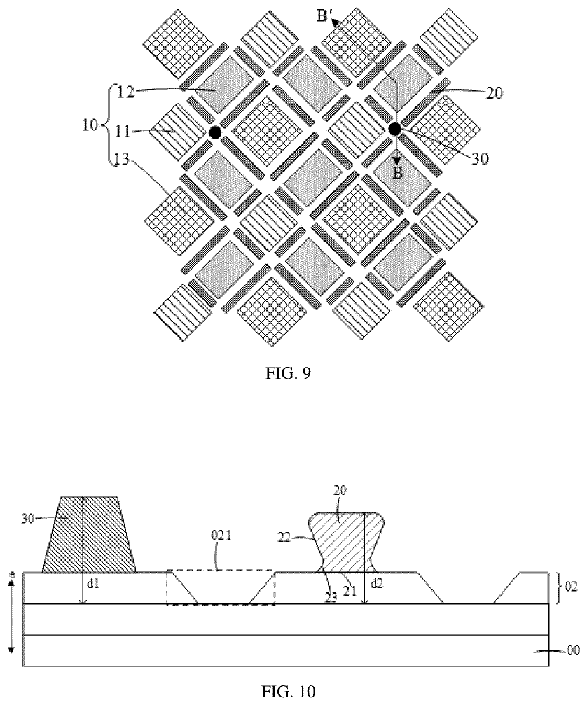

In some embodiments, FIG. 8 is a schematic cross-sectional diagram of another display panel according to an embodiment of the present disclosure. As shown in FIG. 8, the display panel includes a pixel definition layer 02 located on a side of the substrate 00. The pixel definition layer 02 includes a plurality of openings 021. As shown in FIG. 3, the light-emitting device 10 is located in the opening 021. The spacer 20 is located on a side of the pixel definition layer 02 away from the substrate 00. The pixel definition layer 02 includes a base portion 022 and a protrusion portion 023. The protrusion portion 023 protrudes from the base portion 022 to the side away from the substrate 00. The base portion 022 and the opening 021 share a sidewall. In the first cross-section M1, an edge of the base portion 022 extends beyond the protrusion portion 023 along the first direction a. The first direction a is parallel to the plane of the substrate 00. That is, a width of the base portion 022 along the first direction a is greater than a width of the protrusion portion 023 along the first direction a. Along the direction e perpendicular to the plane of the substrate 00, the spacer 20 at least partially overlaps with the protrusion 023. The protrusion 023 includes a first top surface m1 and a first side surface m2 connected to each other. In the first cross-section M1, it can be seen that an angle formed between the first top surface m1 and the first side surface m2 towards the inside of the protrusion 023 is an obtuse angle. The spacer 20 includes a first spacer 20-1 in contact with the first top surface m1. That is, the bottom edge 21 of the first spacer 20-1 is in contact with the first top surface m1. According to this embodiment of the present disclosure, the first spacer 20-1 is provided, and the first spacer 20-1 is provided on the protrusion portion 023 of the pixel defining layer 02, which is equivalent to placing the first spacer 20-1 at the slope position of the pixel defining layer 02, thereby forming a large included angle between the bevel edge 22 of the spacer 20 and the first side surface m2 of the protrusion portion 023, thus better facilitating the film formation of the inorganic encapsulation layer at the bottom of the spacer 20, and thus further improving the encapsulation reliability. In addition, the first spacer 20-1 is provided on the protrusion portion 023, which is equivalent to raising the first spacer 20-1, thereby improving the partition effect on the evaporation material.

In some embodiments, the base portion 022 is made of the same material as the protrusion portion 023, and the base portion 022 and the protrusion portion 023 are integrally formed. During the forming of the display panel, the pixel definition layer 02 may be formed by using a half-grayscale mask process to form the base portion 022 and the protrusion portion 023.

In some other embodiments, the base portion 022 includes a light-shielding material, and the protrusion portion 023 includes a transparent material. In this embodiment, the base portion 022 and the protrusion portion 023 are formed separately. The base portion 022 is made of the light-shielding material, so as to prevent light crosstalk between adjacent light-emitting devices. The protrusion portion 023 is made of the transparent material, so as to prevent large-angle light emitted by the light-emitting device from being shielded and to ensure the light-emitting angle of the light-emitting device.

As shown in FIG. 8, an angle formed between the first side surface m2 and the plane of the substrate 00 and facing the inside of the protrusion portion 023 is a second included angle α, where 10°≤α≤40°. Such a configuration can ensure that a large included angle can be formed between the first side surface m2 of the protrusion portion 023 and the first spacer 20-1, thereby being more conducive to the film formation of the inorganic encapsulation layer at the bottom of the first spacer 20-1, and thus further improving the encapsulation reliability. Additionally, the size process of a is easy to implement in terms of process, with low forming difficulty.

As shown in FIG. 8, along the direction e perpendicular to the plane of the substrate 00, the height of the first side surface m2 is h1, where 0.3 μm≤h1≤0.6 μm. The height h1 of the first side m2 is understood as its length along the direction e. In this embodiment, the height h1 of the first side surface m2 is not excessively large, thereby preventing the excessively high stacked height after stacking the first spacers 20-1 on the protrusion portion 023, thereby affecting the overall thickness of the display panel. In addition, the height h1 of the first side surface m2 is not excessively small, thereby forming a protrusion 023 with a proper size within the process capability range, and thus better achieving the film formation of the inorganic encapsulation layer at the bottom of the spacer 20 in cooperation with the shape of the spacer 20.

In some other embodiments, FIG. 9 is a partial schematic diagram of another display panel according to an embodiment of the present disclosure, and FIG. 10 is a simplified cross-sectional schematic diagram at a position of a tangent line B-B′ shown in FIG. 9. Referring to FIG. 9 and FIG. 10, the display panel includes a support post 30 located on a side of the pixel definition layer 02 away from the substrate 00. The support post 30 is configured to support the mask in the evaporation process to ensure uniform evaporation. A perpendicular distance between a surface of the support post 30 away from the substrate 00 and the substrate 00 is d1, and a perpendicular distance between a surface of the spacer 20 away from the substrate 00 and the substrate 00 is d2, where d1>d2. The arrangement of the support posts 30 on the display panel is not limited in the embodiments of the present disclosure, and FIG. 9 only schematically represent some of the embodiments. When the plane of the substrate 00 is configured as the reference plane, the height of the spacer 20 on the substrate 00 is smaller than the height of the support post 30, thereby ensuring the support post 30 to be used to support the mask in the evaporation process, and thus preventing the height of the spacer 20 from being excessively large to influence the evaporation yield.

Referring to the embodiments of FIG. 8, when the first spacer 20-1 is located on the protrusion portion 023, the height of the first spacer 20-1 on the substrate 00 is also smaller than the height of the support post 30 when the plane of the substrate 00 is the reference plane.

In some embodiments, 0.3 μm≤d1−d2≤0.6 μm. In this embodiment, a difference between d1 and d2 is not excessively large, thereby ensuring a sufficiently large height of the spacer 20, and thus further ensuring the partition effect of the spacer 20 on the evaporation material. The difference between d1 and d2 is excessively small, thereby enabling the mask to be supported by the support post 30 in the evaporation process, and thus avoiding the influence on the evaporation yield.

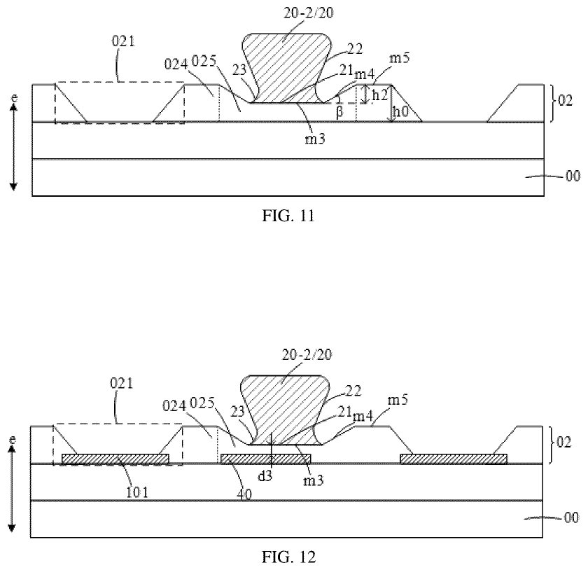

In some embodiments, FIG. 11 is a schematic cross-sectional diagram of another display panel according to an embodiment of the present disclosure. As shown in FIG. 11, the display panel includes a pixel definition layer 02 located on a side of the substrate 00. The pixel definition layer 02 includes a plurality of openings 021. As shown in FIG. 3, the light-emitting device 10 is located in the opening 021. The spacer 20 is located on a side of the pixel defining layer 02 away from the substrate 00. The pixel definition layer 02 includes a base portion 024 and a recessed portion 025 that are integrally formed. The base portion 024 and the opening 021 share a sidewall. The recessed portion 025 includes a first bottom surface m3 and a second side surface m4 connected to each other. The base portion 024 includes a second top surface m5 on a side away from the substrate 00. Along a direction e perpendicular to the plane of the substrate 00, a perpendicular distance between the first bottom surface m3 and the substrate 00 is smaller than a perpendicular distance between the second top surface m5 and the substrate 00. The second side surface m4 connects the first bottom surface m3 and the second top surface m5. The spacer 20 includes a second spacer 20-2 in contact with the first bottom surface m3. In this embodiment, the second spacer 20-2 is provided at a recessed position of the pixel definition layer 02, enabling a small included angle to be formed between the second spacer 20-2 and the second side surface m4 of the recessed portion 025, thereby improving the deposition morphology of the inorganic encapsulation layer at the bottom position of the second spacer 20-2, and thus reducing the formation of the cracks of the inorganic encapsulation layer at the bottom position, and thus improving the encapsulation reliability.

As shown in FIG. 11, along the direction e perpendicular to the plane of the substrate 00, a height of the second side surface m4 is h2, and a maximum thickness of the base portion 024 is h0, where 0.3 μm≤h2≤h0. The height h2 of the second side surface m4 is also equivalent to a recessed depth of the recessed portion 025. When h2 is smaller than h0, the pixel definition layer 02 may be formed by using a grayscale mask process when forming the display panel, so as to form the base portion 024 and the recessed portion 025. According to this embodiment of the present disclosure, the minimum h2 is 0.3 μm, which is easy to implement in terms of process and reduces process difficulty.

As shown in FIG. 11, an angle formed between the second side surface m4 and the plane of the substrate 00 and facing the inside of the recessed portion 025 is a third included angle β, where 10°≤β≤40° Such a configuration can ensure a small included angle formed between the second side surface m4 of the recessed portion 025 and the second spacer 20-2, thereby improving the deposition morphology of the inorganic encapsulation layer at the bottom position of the second spacer 20-2, and thus reducing the formation of the cracks of the inorganic encapsulation layer at the bottom position. Additionally, the size process of B is easy to implement in terms of process, with low forming difficulty.

In an embodiment of the present disclosure, as shown in FIG. 4, the light-emitting device 10 includes a first electrode 101, a light-emitting layer 105 and a second electrode 102 that are stacked. The first electrode 101 is located on a side of the second electrode 102 close to the substrate 00. In some embodiments, FIG. 12 is a schematic cross-sectional diagram of another display panel according to an embodiment of the present disclosure, and FIG. 12 is only simplified and only illustrates the first electrode 101 in the light-emitting device 10. As shown in FIG. 12, the display panel includes a first metal structure located in a same layer as the first electrode 102. Along the direction e perpendicular to the plane of the substrate 00, the second spacer 20-2 at least partially overlaps with the first metal structure 40. Along the direction e perpendicular to the plane of the substrate 00, the distance between the first bottom surface m3 and the first metal structure 40 is d3, where d3≥0.3 μm. When the metal structure is provided below the recessed portion 025, the bottom of the recessed portion 025 and the metal structure are provided to satisfy a certain distance, thereby enabling the recessed portion 025 not to expose the metal structure, enabling the second spacer 20-2 to be in contact with the recessed portion 025 made of a similar material, thus ensuring better adhesion between the second spacer 20-2 and the recessed portion 025 and firmer contact connection.

FIG. 2 illustrates a top view of the display panel. It can be understood that the top view direction of the display panel is the same as the direction of projection onto the plane of the substrate, then the orthographic projection of the spacer 20 onto the substrate coincides with the spacer 20 in the top view. It can be seen from FIG. 2 that the orthographic projection of the spacer 20 onto the substrate partially surrounds the orthographic projection of the light-emitting device 10 onto the substrate. That is, the spacer 20 surrounding the periphery of the light-emitting device 10 does not form a closed pattern, thereby ensuring that the spacer 20 does not completely partition the second electrodes 102, and thus electrically connecting a plurality of second electrodes 102 of a plurality of light-emitting devices 10 on the entire surface of the display panel.

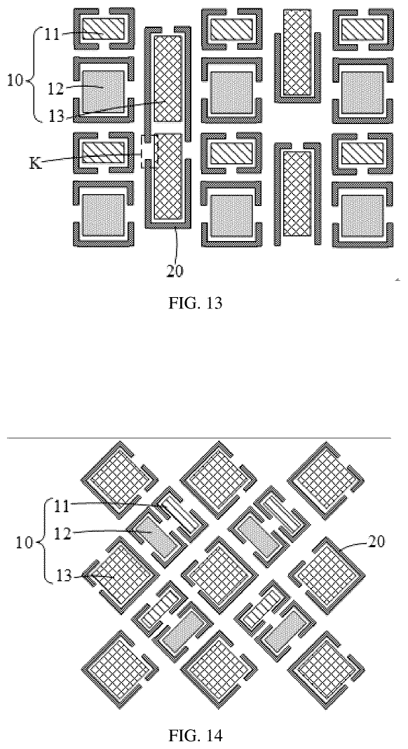

In an embodiment, FIG. 13 is a partial schematic diagram of another display panel according to an embodiment of the present disclosure. As shown in FIG. 13, the light-emitting device 10 includes a first light-emitting device 11, a second light-emitting device 12, and a third light-emitting device 13 with different colors. Along a direction surrounding the light-emitting device 10, the spacer 20 is formed with at least one fracture K. At positions of two adjacent light-emitting devices 10, the fracture K is opposite to the spacer 20 at least partially surrounding another light-emitting device 10. At a position of the fracture K, the organic functional layer may not be partitioned, and the cathode layer formed by the second electrode may also not be partitioned. The fracture K is disposed opposite to the spacer 20 at least partially surrounding another light-emitting device 10, thereby ensuring that the second electrodes in the entire display region are connected to each other, and increasing the current transmission path in the organic functional layer, thus alleviating the lateral leakage current between the light-emitting devices 10.

In another embodiment, FIG. 14 is a partial schematic diagram of another display panel according to an embodiment of the present disclosure. As shown in FIG. 14, the light-emitting devices 10 include a first light-emitting device 11, a second light-emitting device 12, and a third light-emitting device 13 with different colors. Along a direction surrounding the light-emitting device 10, the spacer 20 is formed with at least one fracture K. At positions of two adjacent light-emitting devices 10, the fracture K is opposite to the spacer 20 at least partially surrounding another light-emitting device 10.

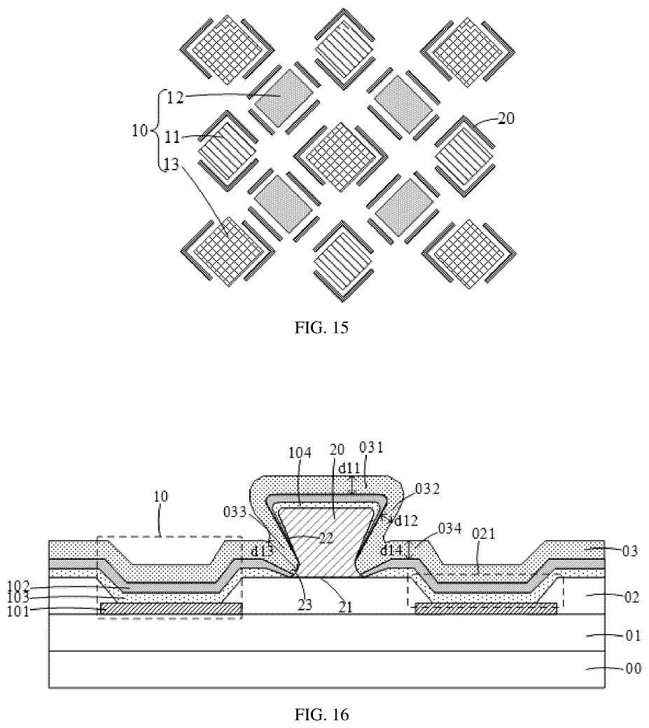

In another embodiment, FIG. 15 is a partial schematic diagram of another display panel according to an embodiment of the present disclosure. As shown in FIG. 15, the light-emitting devices 10 include a first light-emitting device 11, a second light-emitting device 12, and a third light-emitting device 13 with different colors. Along a direction surrounding the light-emitting device 10, the spacer 20 is formed with at least one fracture K. At positions of two adjacent light-emitting devices 10, the fracture K is opposite to the spacer 20 at least partially surrounding another light-emitting device 10.

In some embodiments, FIG. 16 is a schematic cross-sectional diagram of another display panel according to an embodiment of the present disclosure. As shown in FIG. 16, the display panel includes an inorganic encapsulation layer 03 covering the light-emitting device 10 and the spacer 20 on a side of the light-emitting device 10 and the spacer 20 away from the substrate 00 to form an entire layer. The inorganic encapsulation layer 03 includes a first sub-portion 031, a second sub-portion 032, a third sub-portion 033 and a fourth sub-portion 034 that are sequentially connected. The first sub-portion 031 covers a top surface of the spacer 20 on a side away from the substrate 00. The second sub-portion 032 covers the bevel edge 22. The third sub-portion covers the arc edge 23. The fourth sub-portion 034 covers the pixel definition layer 02. A thickness of the first sub-part 031 is d11, a thickness of the second sub-part 032 is d12, a thickness of the third sub-part 033 is d13, and a thickness of the fourth sub-part 034 is d14. The thickness d11 of the first sub-portion 031 is equal to the thickness d14 of the fourth sub-portion 034, the thickness d12 of the second sub-portion 032 is smaller than the thickness d11 of the first sub-portion 031, and the thickness d13 of the third sub-portion 033 is greater than the thickness d11 of the first sub-portion 031. In this embodiment of the present disclosure, the inorganic encapsulation layer 03 is formed after the light-emitting device 10 is formed, a top surface of a side of the spacer 20 away from the substrate 00 is substantially parallel to the plane of the substrate 00. A plane of the pixel defining layer 02 is substantially parallel to the plane of the substrate 00. The first sub-portion 031 covers the top surface of the side of the spacer 20 away from the substrate 00. The fourth sub-portion 034 covers the pixel defining layer 02, thereby enabling a thickness d11 of the first sub-portion 031 to be equal to a thickness d14 of the fourth sub-portion 034. Since the bevel 22 of the spacer 20 is inclined relative to the plane of the substrate 00, the thickness of the second sub-portion 032 covering the bevel 22 is relatively small. The position of the arc edge 23 is equivalent to stacking of the inorganic material deposited in a transverse direction and a longitudinal direction, thereby enabling the thickness d13 of the third sub-portion 033 at this position to be maximum.

In an embodiment of the present disclosure, the spacer 20 is made of a negative photoresist material. The exposed portion of the negative photoresist material is insoluble in the developing solution due to cross-linking and curing, while the unexposed portion is soluble in the developing solution. The negative photoresist material can be used to form the spacer 20 with an approximately inverted trapezoidal shape.

In the related art, the spacer is generally made of a thermosensitive photoresist material. There is a baking and heating step between the exposure process and the development process. Relying solely on light irradiation in the exposure process cannot make the photoresist material fully react and cure, thus it needs to provide a baking and heating process to cure and shape the spacer.

In an embodiment of the present disclosure, the negative photoresist material includes the photosensitive negative photoresist material. The photosensitive negative photoresist material is more sensitive to light. When forming the spacer 20 by the photosensitive negative photoresist material, no baking process is needed between the exposure process and the development process. Then the IUV process is added after the development process to repair the morphology of the spacer 20 required in the embodiments of the present disclosure, and finally the morphology is shaped by high-temperature curing.

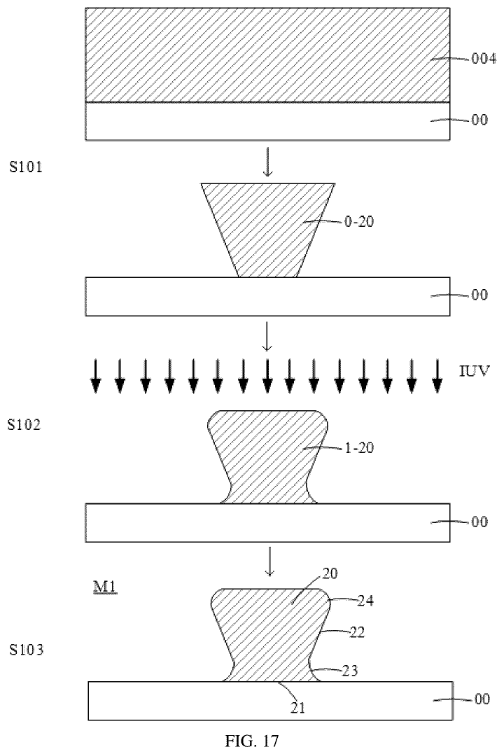

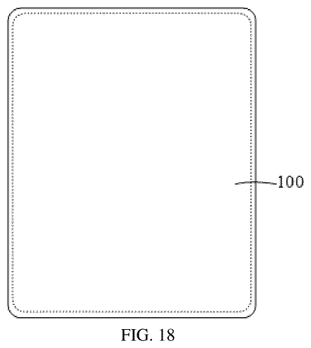

Based on a same inventive concept, an embodiment of the present disclosure further provides a forming method for a display panel, including: forming a light-emitting device and a spacer on a side of a substrate, an orthographic projection of the spacer onto the substrate is located between orthographic projections of adjacent light-emitting devices on the substrate. FIG. 17 is a flowchart of a forming method for a display panel according to an embodiment of the present disclosure. As shown in FIG. 17, the forming method for the spacer includes the following steps.

At S101, the photoresist material 004 is coated, and an embryonic form of the spacer is formed by an exposure-development step. In an embodiment, the coated photoresist material 004 is a photosensitive negative photoresist material. The embryonic form 0-20 of the spacer has an approximately inverted trapezoidal shape.

At S102, IUV irradiation treatment is performed on the embryonic form of the spacer 0-20 to obtain an initial form 1-20 of the spacer. The IUV light refers to ultraviolet light with a wavelength of 365 nm. The photosensitive negative photoresist material is sensitive to IUV light. IUV irradiation causes the carboxyl groups and aldehyde groups in the photosensitive negative photoresist to undergo further reactions. During the reaction process, molecular rearrangement and aggregation result in the formation of an arc edge at the bottom corner part of the embryonic form 0-20 of the spacer. This step modifies the morphology of the embryonic form 0-20 of the spacer.

At S103, the initial form 1-20 of the spacer is cured to obtain the spacer 20. In an embodiment, the curing temperature is within a range from 200° C. to 300° C. After the curing treatment, the spacer 20 includes an arc edge 23. The display panel is provided with a first cross-section M1 perpendicular to the plane of the substrate 00. In the first cross-section M1, the spacer 20 includes a bottom edge 21, a bevel edge 22 and an arc edge 23. The bottom edge 21 is an edge of the spacer 20 close to the substrate 00. The arc edge 23 connects the bottom edge 21 and the bevel edge 22. It can be seen that the angle formed between the bevel edge 22 and the plane of the substrate 00 towards the outside of the spacer 20 is an acute angle. The arc edge 23 is recessed towards the inside of the spacer 20.

By adopting the forming method according to the embodiments of the present disclosure, firstly, the embryonic form 0-20 of the spacer is formed through the exposure and development process; then the embryonic form 0-20 of the spacer is subjected to the IUV irradiation process to obtain the initial form 1-20 of the spacer. The IUV irradiation can cause the photoresist material to undergo further reactions. Molecular rearrangement and aggregation result in the formation of an arc edge at the bottom angle of the embryonic form 0-20 of the spacer, thereby obtaining the initial form 1-20 of the spacer; finally, a spacer 20 with an arc edge 23 at the bottom angle position is obtained through the curing treatment. When forming the inorganic encapsulation layer, the inorganic material may be well deposited and smoothly transited at the arc bottom edge 23 of the spacer 20, avoiding the problem of forming encapsulation cavities and cracks at the bottom angle of the spacer 20, and thus improving the encapsulation reliability of the display panel.

In some embodiments, in step S102, the IUV irradiation process modifies the morphology of the embryonic form 0-20 of the spacer at the position of the bottom angle, and modifies the morphology of the embryonic form 0-20 of the spacer at the corner position on the side away from the substrate 00, so that an arc corner is formed at the corner position. As shown in FIG. 17, the step S103 of curing the initial form 1-20 of the spacer to obtain the spacer 20 further includes the following steps. The spacer 20 is provided with an arc corner 24, and a corner of an end of the spacer 20 away from the substrate 00 in the first cross-section M1 is the arc corner 24. The spacer 20 obtained by the forming method provided by this embodiment of the present disclosure is provided with an arc edge 23 at a position of the bottom angle, and a corner at an end away from the substrate 00 is an arc corner 24. By using the arc edge 23, the inorganic encapsulation layer can be well deposited at the bottom of the spacer 20, thereby avoiding the problem of forming encapsulation cavities and cracks at the bottom angle of the spacer 20. Using the arc corner 24 may facilitate film formation and extension of the inorganic encapsulation layer on the bevel edge 22, and the cooperation between the arc bottom angle and the arc corner 24 on the spacer 20 may enable the inorganic encapsulation layer to form an entire layer, thereby improving the encapsulation reliability.

Based on a same inventive concept, an embodiment of the present disclosure further provides a display device. FIG. 18 is a schematic diagram of a display device according to an embodiment of the present disclosure. As shown in FIG. 18, the display device includes the display panel 100 provided by any embodiment of the present disclosure. The structure of the display panel 100 has been described in the above embodiments, and will not be repeated herein. The display device provided by the embodiments of the present disclosure may be, for example, an electronic device having a display function, such as a mobile phone, a tablet, a computer, a television, and a smart wearable product.

The above description merely illustrates some preferred embodiments of the present disclosure and is not intended to limit the present disclosure, and any modifications, equivalent substitutions, improvements and the like made within the spirit and principle of the present disclosure should be included within the scope of the present disclosure.

It should be noted that, the above-described embodiments are merely for illustrating the present disclosure but not intended to provide any limitation. Although the present disclosure has been described in detail with reference to the above-described embodiments, it should be understood by those skilled in the art that, it is still possible to modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, comprising:
a substrate; and
light-emitting devices and spacers that are located on a same side of the substrate;
wherein an orthographic projection of one of the spacers onto the substrate is located between orthographic projections of adjacent ones of the light-emitting devices onto the substrate;
the display panel has a first cross-section perpendicular to a plane of the substrate; and
in the first cross-section, one of the spacers comprises a bottom edge, a bevel edge and an arc edge; the bottom edge is an edge of the spacer close to the substrate, the arc edge connects the bottom edge and the bevel edge, an angle formed between the bevel edge and the plane of the substrate and facing outside of the spacer is an acute angle, and the arc edge is recessed towards inside of the spacer.

2. The display panel according to claim 1, wherein
along a direction perpendicular to the plane of the substrate, a height of the arc edge is H1; along a first direction, a width of the arc edge is W1, and the first direction is parallel to the plane of the substrate;
where 0.4≤H1/W1≤2.5.

3. The display panel according to claim 2, wherein
$$0.2 μm \leq H 1 \leq 0.5 μm , and 0.2 μm \leq W 1 \leq 0.5 μm .$$

4. The display panel according to claim 1, wherein
in the first cross-section, along a first direction, the arc edge does not exceed an end edge of the spacer away from the substrate, and the first direction is parallel to the plane of the substrate.

5. The display panel according to claim 4, wherein
along the first direction, a distance between the arc edge and the end edge of the spacer away from the substrate is ΔW, and ΔW≥h/(3* tan θ), where h denotes a height of the spacer along a direction perpendicular to the plane of the substrate, and θ is a first included angle formed between the bevel edge and the plane of the substrate and facing outside of the spacer.

6. The display panel according to claim 1, wherein
the display panel comprises a pixel definition layer located on a side of the substrate, the pixel definition layer comprises openings, and the light-emitting devices are located in the openings; the spacers are located on a side of the pixel definition layer away from the substrate; and
the arc edge is in contact with a surface of the pixel defining layer away from the substrate.

7. The display panel according to claim 1, wherein
a corner of an end of the spacer away from the substrate in the first cross-section is an arc corner.

8. The display panel according to claim 7, wherein
along a direction perpendicular to the plane of the substrate, a height of the arc corner is H2; and along a first direction parallel to the plane of the substrate, a width of the arc corner is W2, where 0.5≤H2/W2≤2.

9. The display panel according to claim 8, wherein
$$0.5 μm \leq H 2 \leq 0.9 μm , and 0.5 μm \leq W 2 \leq 0.9 μm .$$

10. The display panel according to claim 7, wherein
along a direction perpendicular to the plane of the substrate, a height of the arc edge is H1, and a height of the arc corner is H2, where H2>H1; and/or along a first direction parallel to the plane of the substrate, a width of the arc edge is W1, and a width of the arc corner is W2, where W2>W1.

11. The display panel according to claim 7, wherein
along a direction perpendicular to the plane of the substrate, a height of the arc edge is H1, a height of the arc corner is H2, and a height of the spacer is h, where h−H1−H2≥h/3.

12. The display panel according to claim 1, wherein
an angle formed between the bevel edge and the plane of the substrate and facing outside of the spacer is a first included angle θ, where 45°≤θ≤75°.

13. The display panel according to claim 1, wherein
the display panel comprises a pixel definition layer located on a side of the substrate, the pixel definition layer comprises openings, and the light-emitting devices are located in the openings; the spacers are located on a side of the pixel definition layer away from the substrate;
the pixel defining layer comprises a base portion and a protrusion portion protruding from the base portion along a direction away from the substrate; the base portion and one of the openings share a sidewall; in the first cross-section, an edge of the base portion exceeds the protrusion portion along a first direction parallel to the plane of the substrate; along a direction perpendicular to the plane of the substrate, one of the spacers at least partially overlaps with the protrusion portion; the protrusion portion comprises a first top surface and a first side surface connected to each other; and in the first cross-section, an angle formed between the first top surface and the first side surface and facing inside of the protrusion portion is an obtuse angle; and
the spacers comprise a first spacer in contact with the first top surface.

14. The display panel according to claim 13, wherein
the base portion and the protrusion portion are integrally formed.

15. The display panel according to claim 13, wherein
the base portion comprises a light-shielding material, and the protrusion portion comprises a transparent material.

16. The display panel according to claim 13, wherein
an angle formed between the first side surface and the plane of the substrate and facing inside of the protrusion portion is a second included angle α, where 10≤α≤40°.

17. The display panel according to claim 13, wherein
along the direction perpendicular to the plane of the substrate, a height of the first side surface is h1, where 0.3 μm≤h1≤0.6 μm.

18. The display panel according to claim 1, further comprising a support post and a pixel definition layer located on a side of the substrate, wherein the support post is located on a side of the pixel definition layer away from the substrate; and
a perpendicular distance between a surface of the support post away from the substrate and the substrate is d1, and a perpendicular distance between a surface of the spacer away from the substrate and the substrate is d2, where d1≥d2.

19. The display panel according to claim 18, wherein 0.3 μm≤d1−d2≤0.6 μm.

20. The display panel according to claim 1, wherein
the display panel comprises a pixel definition layer located on a side of the substrate, the pixel definition layer comprises openings, and the light-emitting devices are located in the openings; the spacers are located on a side of the pixel definition layer away from the substrate;
the pixel definition layer comprises a base portion and a recessed portion, the base portion and the recessed portion are integrally formed; the base portion and one of the openings share a sidewall; the recessed portion comprises a first bottom surface and a second side surface connected to each other, and the base portion comprises a second top surface away from the substrate; along a direction perpendicular to the plane of the substrate, a perpendicular distance between the first bottom surface and the substrate is smaller than a perpendicular distance between the second top surface and the substrate; and the second side surface connects the first bottom surface and the second top surface; and
the spacers comprise a second spacer in contact with the first bottom surface.
